(19) United States
(12) Patent Application Publication
(10) Pub. No.: US 2012/0049309 A1
(43) Pub. Date: Mar. 1, 2012

(54) SMARTCARD INTEGRATED WITH A FINGERPRINT IMAGE ACQUISITION SENSOR AND A METHOD FOR MANUFACTURING THE SMARTCARD

(76) Inventors: Shoichi Kiyomoto, Tokyo (JP); Shinil Cho, Allison Park, PA (US)

(21) Appl. No.: 12/906,079

(22) Filed: Oct. 16, 2010

(30) Foreign Application Priority Data
Sep. 1, 2010 (JP) 2010-195814

(51) Int. Cl. H01L 31/02

(52) U.S. Cl. 257/434; 257/E31.113

(57) ABSTRACT

The Problems

To provide a smartcard that embeds a fingerprint image acquisition sensor, having thickens of 0.76 mm or less compiling with the International Standard organization (ISO).

Means for Solving the Problem

A smartcard comprising a core substrate which is configured with a film substrate 21 on which a fingerprint image acquisition sensor IC chip 11, an electric circuit pattern and accompanying electrical, and a reinforcing metal or composite plate 1 which is adhered to the back surface of the fingerprint image acquisition sensor IC chip 11; an over sheets 31 and an under sheet 33, which are made of thermoplastic or paper, sandwiching the core substrate 33, where the over sheet 31 and the under sheet 33 are attached with a thermal adhesive sheet, which functions as a mechanical buffer to protect the electrical components from external stress. The adhesive sheet is made of urethane rubber or similar substance.

### FIELD OF THE INVENTION

The present invention relates to a biometric smartcard which embeds a sensor for acquiring a fingerprint image, and also a method for manufacturing the smartcard.

### BACKGROUND OF THE INVENTION

A smartcard integrated with an Integrated Circuit (IC) for data processing is often utilized for various applications because of its adequate memory capacity for information storage and tighter security for user identification protection. It is believed that the IC chip-based smartcard would replace the magnetic stripe type card very soon. In particular, European and Asian public transportations including trains and subways have adopted smartcards of non-contact types for improving the efficiency of the fare payment system. In some cases, smartcards may be used for vending machines.

For carrying and using a smartcard, the International Standard Organization (ISO) requires the physical dimension of a smartcard to be height of 85.6 mm, width of 54.0 mm, and thickness of 0.76 mm or less. Because the size of a smartcard is specified by the ISO is critical for universal applications, an IC chip embedded in the card should also meet with the size requirement. However, it is a technological challenge to fabricate an ultra thin IC chip that performs various tasks of data communication and process well. Research and development for designing an antenna and/or a modulator for better data communication by an ultra thin IC chip in a contactless smartcard have been also conducted for higher performance. For example, the Japanese Patent Application Kokai Publication numbers 1998-86569 and 2005-301407 disclose several inventions.

For embedding a sensor into a smartcard for acquiring a fingerprint image, the Japanese Patent Application Kokai Publication number 1996-138022 discloses a fingerprint image acquisition sensor IC chip which has external connection terminals (the “pads”) formed at the backside of the sensor chip to connect the sensor chip with electrical circuits which are formed on the film substrate of the smartcard, and through electrodes which penetrates the sensor IC chip to connect the top and the bottom surfaces electronically for mounting the fingerprint image acquisition sensor on the smartcard easier. A plural number of the fingerprint image acquisition sensor IC chips are fabricated on a silicon wafer for mass production.

For manufacturing the fingerprint image acquisition sensor IC chip, a prior method which is described in Flowchart 4a comprises of the following steps: a step 51 of layering a plural number of the fingerprint image acquisition sensor IC chips 11 for maximizing the number of the sensor IC chips 11 yielding from a given size of silicon wafer, i.e., for minimizing the gap distance between two adjacent chips fabricated on the silicon wafer; a step 52 of surface coating to protect the sensor IC chips 11 from electrostatic discharge (ESD); a step 53 of dicing the sensor IC chips 11 to cut to separate the sensor IC chip 11; the step 54 of bonding gold wires between the pads 14 and the connection terminals of the package; a step 55 of encapsulating the fine gold wires and the weak bondings by applying an epoxy agent; a step 56 of applying passivation on the sides of the sensor IC chip.

### SUMMARY OF THE INVENTION

### Problems that the Invention is to Solve

Because the method disclosed by the Japanese Patent Application Kokai Publication No. 1996-138022 does not only employ a series of sophisticated fabrication processes, which requires a high manufacturing overhead, but also the physical size of the IC chip is large due to a larger area for the pads, yielding less number of IC chips from a given size of silicon wafer. Therefore, this method of the prior art inevitably increases the total manufacturing cost so high that use of a smartcard with the fingerprint image acquisition IC chip may not be justified for most applications.

The wire bonding step 54 of the prior art in Flowchart 4a requires encapsulation agent that covers the gold wire loops to reduce the stress on the gold wires. Because the coverage requires a certain thickness, the fingerprint image acquisition sensor IC chip fabricated by applying this method often becomes thicker than the maximum thickness 0.76 mm of the ISO standard.

There is also a technological problem of the mechanical strength of a smartcard of the prior art. Reducing the area of the encapsulation for thinning the card may also degrade the mechanical strength of the smartcard, which results in a thin film of the smartcard peeled off during the fabrication process, and producing more defective cards.

Although a fingerprint image acquisition sensor IC chip must be thinner than a smartcard of the standard thickness of 0.76 mm or less, a thinner an IC chip is mechanically weaker for external stress such as bending the card.

Smartcards are always exposed to risk of damage caused by the ESD. Furthermore, the fingerprint image acquisition sensor IC chip embedded in the smartcard is more susceptible to the ESD because a finger physically touches the surface of the sensor IC chip and discharges the static electricity to it. In particular, the control circuit mounted on the layered surface of the sensor chip is most vulnerable to the ESD.

In addition to the physical threads, the smartcard is facing the security thread where the personal identification of the owner of the smartcard could be stolen. Biometrics and fingerprint authentication in particular should provide the highest degree of security. However, we recently witness many criminal incidents of attempting to breach the biometric security by using fake fingerprints. For this reason, it is highly demanded that detection of both liveness and fakeness of a finger be implemented in the fingerprint image acquisition sensor. As a smartcard which equips with the biometric fingerprint authentication function is used as a means for commercial payments and transactions, security of the smartcard 110 becomes critical for the identification protection for each use.

### Means for Solving the Problems

Considering the above technological challenges, the present invention provides a smartcard which packages a die of an IC chip of a fingerprint image acquisition sensor by using a thin film substrate, which is similar to one used in a mobile device such as a portable phone, with the following structure for the device integration: an aperture is fabricated through the film substrate so that the IC chip of a fingerprint image acquisition sensor may be exposed through the aperture for allowing a finger to contact the sensing area, where the circumference of the IC chip is adhered to the backside of the film substrate with adhesive, and electrical circuits and components for driving the fingerprint image acquisition sensor IC chip are mounted on the backside of the film substrate.

The present invention also provides a smartcard which is integrated with a fingerprint image acquisition sensor IC chip where the side surfaces of the IC chip is sealed for obtaining adequate mechanical strength, i.e., adhesive is applied on the side of the pads and the electrical components of the IC chip for encapsulation and reinforcement.

Furthermore, the present invention provides a smartcard which embeds a fingerprint image acquisition sensor IC chip where an additional plate is attached to reinforce the backside of the IC chip whereas the sides of the IC chip is encapsulated for adequate mechanical strength after adhering the connecting terminals for electrical circuits and the components.

In addition, the present invention provides a smartcard integrated with a fingerprint image acquisition sensor IC chip which equips with a control circuit unit for acquiring data from the fingerprint image acquisition sensor, controlling and digitizing the acquired data, and then outputting the digitized data, where an predetermined size of an electrically grounded conductive pattern is formed on the thin film substrate of the sensor IC chip to surround the control unit for protection from the ESD.

The present invention also provides a smartcard which embeds a fingerprint image acquisition sensor IC chip where there is a strip of an electrode pattern which is formed along the outer circumference of the aperture of the thin film substrate so that the pattern electrode may detect a signal from a finger as it touches the sensing area of the IC chip as well as the pattern electrode to detect a spoof finger.

### Effect of the Invention

As disclosed above, the present invention may manufacture a smartcard of thickness of approximately 0.7 mm by layering the fingerprint image acquisition sensor IC chip 11 of thickness approximately 0.2 mm, the thin film 21 of thickness approximately 0.1 mm, and the over sheet 31 and the under sheet 33 of thickness of approximately 0.15 mm each, which add to the total thickness of approximately 0.6 mm, which is less than the widely accepted international standard thickness of 0.76 mm.

At the same time, because the present invention allows the physical size of the fingerprint image acquisition sensor IC chip 11 to be smaller while keeping a certain mechanical strength, the yield of the IC chips per a single silicon wafer will be higher, which may reduce the production cost.

Furthermore, forming the conductive pattern 26 on the film substrate 21 may prevent the controlling unit 15, which is the most vulnerable part of the fingerprint image IC chip 11, from being damaged by the ESD.

In addition, the smart card which embeds the fingerprint image acquisition sensor IC chip of this invention may detect a spoof finger placed on the fingerprint image IC chip by measuring an electric signal such as the dielectric constant and the electrostatic capacitance generated between the contacting finger and the conductive frame pattern 27 which is exposed through an aperture of the over sheet on the surface of the film substrate is appropriately determined so that the finger also directly touches the conductive pattern 27.

In other words, the present invention may implement a smartcard integrated with a fingerprint image acquisition sensor IC chip while compling with the international standard, enhancing the mechanical strength, and the logical security of the smartcard, i.e., protection of the sensor IC chip from the ESD as well as from the mechanical stress, and detecting a spoof finger from which a fingerprint image is acquired by the embedded image sensor.

### BRIEF DESCRIPTION OF THE DRAWINGS

FIG. 1 is an exploded prospective view of a smartcard integrated with a fingerprint image acquisition sensor IC chip as an embodiment of the present invention.

FIG. 2 is a schematic diagram of configuration of the fingerprint image acquisition sensor IC chip on the smartcard.

FIG. 3 is a schematic diagram of the film substrate on which the fingerprint image acquisition sensor IC chip is mounted, and the pad section is adhered.

FIGS. 4a and 4b show flow charts of a method for packaging a fingerprint image acquisition sensor chip of the prior art, and a method for fabricating the core substrate that mounts the fingerprint image acquisition sensor IC chip of this invention, respectively.

FIGS. 5a and 5b depict an exploded prospective view of the encapsulation process where adhesive agent is coated on the side surface of the fingerprint image acquisition sensor IC chip for fixing the chip with the film substrate, and a side view of the fingerprint image acquisition sensor IC chip and the film substrate after completing the encapsulation process, respectively.

FIGS. 6a and 6b show an exploded prospective view of the process of putting the fingerprint image acquisition sensor IC chip, the film substrate, and a reinforcing plate together, and a side view of the fingerprint image acquisition sensor IC chip, the film substrate, and the reinforcing plate after the assembly, respectively.

FIG. 7 depicts an exploded prospective view of the fingerprint image sensing part of the smartcard of this invention where the over sheet has an aperture though which the rectangular conductive strip pattern surrounding the aperture of the film substrate is exposed so that a finger directly touches the conductive strip as it contacts with the surface of the fingerprint image acquisition sensor IC chip. In this figure, the over sheet 31 shows the exposure of the rectangular conductive strip after adhering with the film substrate.

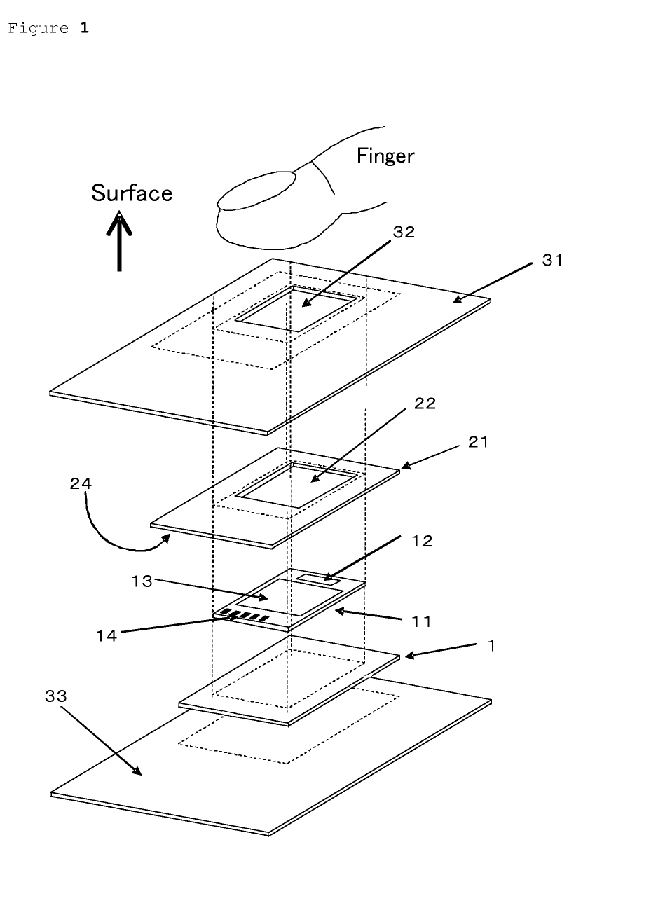

### DETAILED DESCRIPTION OF THE INVENTION

### Embodiment of the Invention

A smartcard as an embodiment of the present invention comprises with a core substrate which is configured with a fingerprint image acquisition sensor IC chip 11, a film substrate 21 of an electrical circuit pattern on which electrical components are mounted, and a reinforcing plate 1, which is made of metal or composite material, adhered to the backside of the fingerprint image acquisition sensor IC chip 11; and the over sheet 31 and the under sheet 33, which are of thermo plastic resin or paper, where a sheet of adhesive sheet, which also functions as mechanical buffer to protect the electronic components from the external stress is placed between the core substrate and each of the over sheet 31 and the under sheet 33, adhered with thermocompression. The adhesive sheet is preferably made of adhesive agent of urethane rubber.

### Embodiment 1

Referring to an exploded prospective view of the smartcard of the present invention, the structure of the smartcard embedding a fingerprint image acquisition sensor IC chip and a method for packaging the fingerprint image acquisition sensor IC chip are disclosed hereafter.

The core substrate of the smartcard of the present invention is configured with the fingerprint image acquisition sensor IC chip 11, the film substrate 21 of an electrical circuit pattern on which electrical components are mounted, and the reinforcing plate 1, which is made of metal or composite material, adhered to the backside of the fingerprint image acquisition sensor IC chip 11.

In addition, the over sheet 31 and the under sheet 33, each of which is made of thermoplastic resin or paper, are adhered to sandwich the core substrate, as the final manufacturing step of forming the smartcard.

In this embodiment of the present invention, the film substrate may be made of various materials including polyimide resin of thickness approximately 0.03 mm, glass epoxy resin substrate of thickness approximately 0.1 mm, and polyester of thickness approximately 0.05 mm.

The electrical circuit pattern which includes the connection terminal 25 for connecting the fingerprint image IC chip 11 with the core substrate and required components are mounted on the region 24 underneath of the film substrate 21.

The fingerprint sensor IC chip 11 is fabricated on a silicon wafer.

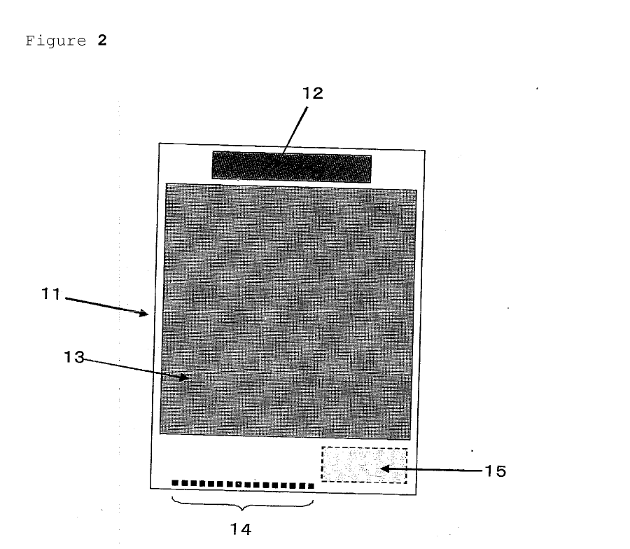

FIG. 2 shows a schematic diagram of the structure of the fingerprint sensor IC chip 11 which is configured with a sensor 12 for detecting a finger placement and simultaneously checking its liveness, a sensing area 13 for acquiring a fingerprint image, a control unit 15 for driving the fingerprint sensor to digitize the input signal and output the digitized signal, and the connection terminal 14 for interfacing the fingerprint image acquisition sensor IC chip with external devices and receiving electrical power from a external power supply.

By downsizing the connection terminal 14, the fingerprint image acquisition sensor IC chip 11 may be within a predetermined size such as 8.5 mm of length and 11 mm of width, which makes possible to produce over 130 pieces of the fingerprint image acquisition sensor IC chips 11 from a 6-inch silicon wafer which is one of the smallest silicon wafers currently used in mass production of semiconductor devices.

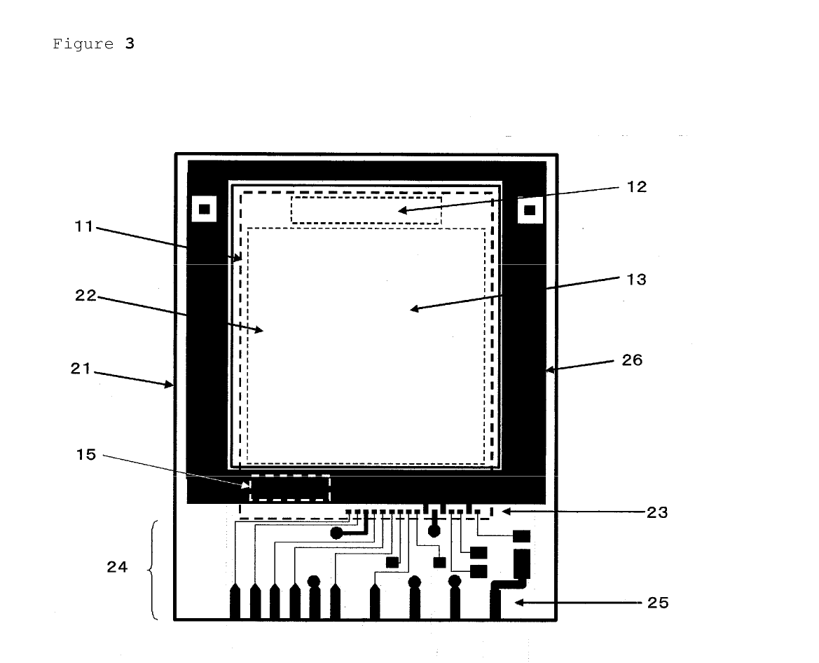

FIG. 3 is a schematic diagram of the film substrate 21, viewing the backside surface of the film substrate 21 (the “component surface,” hereafter) on which the electrical circuit pattern and the electrical components mounted on the circuit pattern are placed. Although FIG. 3 depicts a simplified circuit pattern which shows only connections required for data communication with an external circuit which is formed on a separate substrate as part of the core substrate, it is possible to mount various units such as a high performance Central Processing Unit (CPU) for executing the fingerprint authentication algorithm, a memory unit for storing data of an acquired fingerprint such as the fingerprint image and characteristic points, an external connection terminal for a contact type smart card, and an antenna and its telecommunication control unit of a non-contact type smart card.

In the region 24, there formed the connection terminal 23 which is adhered to the external connection terminal 14 of the fingerprint image acquisition sensor IC chip 11.

In addition, in the region 24, in the case of a smartcard of the contact type, there may be a contact point for an external connection terminal formed on the circuit pattern or a separate substrate on the core substrate; in the case of a smartcard of the non-contact type, there may be an antenna pattern or a modulation circuit formed on the circuit pattern or a separate substrate on the core substrate; or in the case of a smartcard of the hybrid type, there may be both of the aforementioned additional circuitries formed on the core substrate.

If the additional circuitry is formed on the separate substrate as describe above, it is placed on the same side of the surface as the component surface of the film substrate 21, and then electrically connection is established between the separate substrate and the component surface.

The fingerprint authentication unit including the CPU and the memory unit required for processing the fingerprint may be mounted on either the separate substrate or the film substrate 21.

On the film substrate 21, there formed the aperture 22, which locates in the interior area of the bold black rectangular frame, exposing the sensing area 13 and the detecting sensor part 12 of the fingerprint image acquisition sensor IC chip 11 for data acquisition.

The over sheet 31 and the under sheet 33 are thermo-compressed to the core substrate, by sandwiching adhesive sheets, which also function as mechanical buffer to protect the electronic components from the external stress, respectively. The adhesive sheet is made of adhesive agent of urethane rubber.

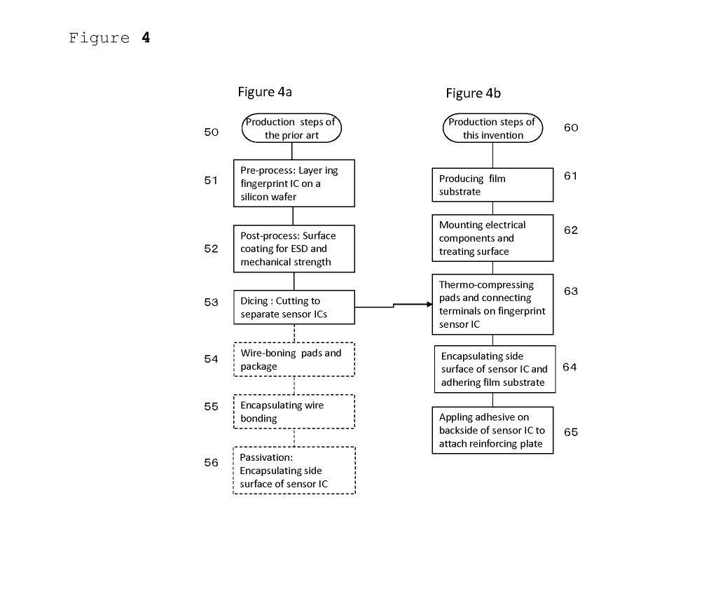

Referring to FIG. 4b, the manufacturing method of the core substrate of this invention consists of the following steps: a step 61 of preparing the film substrate 21, a step 62 of forming an electric circuit pattern on the film substrate 21, soldering electrical components on the circuit pattern, a step 63 of thermo-compressing the fingerprint sensor IC chip 11, which is diced with a conventional dicing method 53, overlaying the connection terminal 14 onto the terminal 23 of the film substrate 21.

In the thermo-compression step, solder may be heaped on the compressing surfaces prior to the thermo-compression. An alternative method for low temperature thermo-compression may be employed by using an anisotropic conductive film, anisotropic conductive paste, or solder.

Because the adhesion strength is still inadequate due to the small adhered area, the manufacturing method of the core substrate of this invention has another step 64 of coating additional adhesive such as epoxy adhesive to the side of the fingerprint image acquisition sensor IC chip 11. This step increases the adhesion strength and at the same time, encapsulates the fingerprint image acquisition sensor IC chip 11.

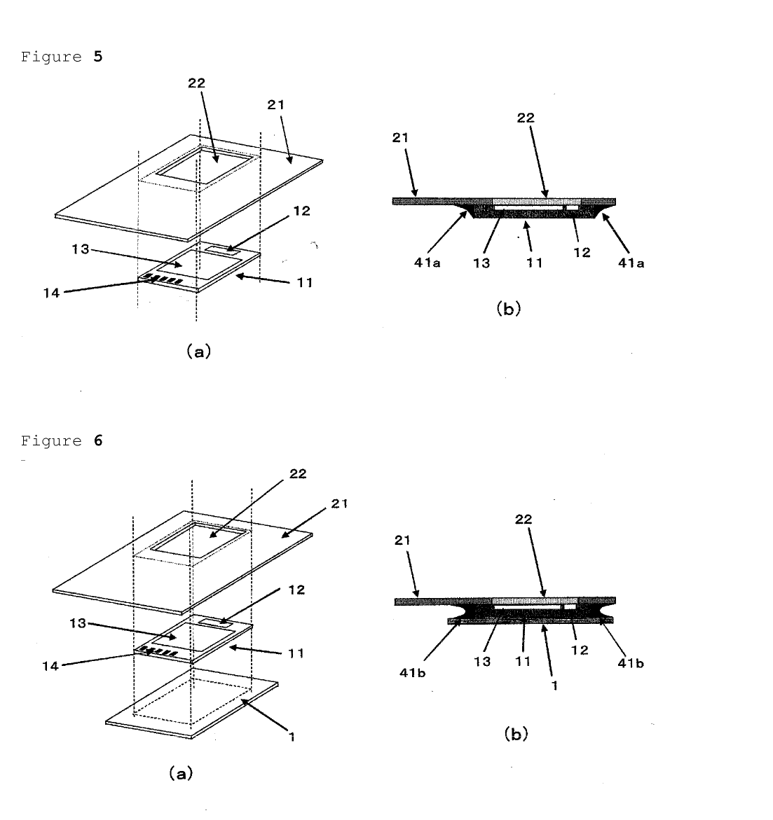

FIG. 5 shows that the fingerprint image acquisition sensor IC chip 11 adhered with the film substrate 21 by coating the epoxy adhesive on the side surface, and the epoxy adhesive is a passivation layer which protects the side surface of the fingerprint image acquisition sensor IC chip 11.

In the manufacturing method of the core substrate of this invention, it is also possible to add another step 65 of adhering a reinforcing plate such as a metal plate to the backside of the fingerprint image acquisition sensor IC chip 11 prior to curing the epoxy adhesive coated on the side surface by adjusting the time for cure of the epoxy adhesive. This additional step applies to spread another adhesive on the backside of the fingerprint image acquisition sensor IC chip 11 without introducing air bubbles in the spread adhesive, and then fixes the reinforcing plate on the coated backside of the fingerprint image acquisition sensor IC chip 11, which enhances the integrity of reinforcement and encapsulation of the fingerprint image acquisition sensor IC chip 11.

FIG. 6 shows that after completing the manufacturing method of the core substrate of this invention, the fingerprint image acquisition sensor IC chip 11 and the film substrate 21 are firmly adhered together, and also the reinforcing metal plate 1 is securely fixed to the backside of the fingerprint image acquisition sensor IC chip 11 on which the adhesive is applied and spread without introducing air bubbles.

FIG. 6b illustrates that the reinforcing adhesive layer 41b protects the side surface of the fingerprint image acquisition sensor IC chip 11.

The time for curing the epoxy adhesive may be adjusted by changing either the mixing ratio of the adhesive components or the curing temperature. The reinforcing plate 1 may be made of metal such as stainless steel of thickness 0.1 mm.

In this embodiment of the present invention, there formed a rectangular conductive strip pattern 26 which surrounds the aperture 22 in the electoral circuit pattern which is formed on the film substrate 21 which is shown in FIG. 3.

The conductive strip pattern 26 is adequately wide for protecting the controller unit 15, which is most vulnerable to the electrostatic charge accumulated on the fingerprint image acquisition sensor IC chip 11, and is grounded.

In other words, when electrostatic charge zaps the vulnerable controller unit 15, the conductive strip pattern 26 works as a discharge electrode to flow the electrostatic charge to the ground, protecting the controller unit 15 from being damaged.

Furthermore, the present invention proposes a method for detecting a spoof finger placed on the fingerprint image acquisition sensor IC chip 11 by measuring the dielectric constant or the electrical capacity of the finger.

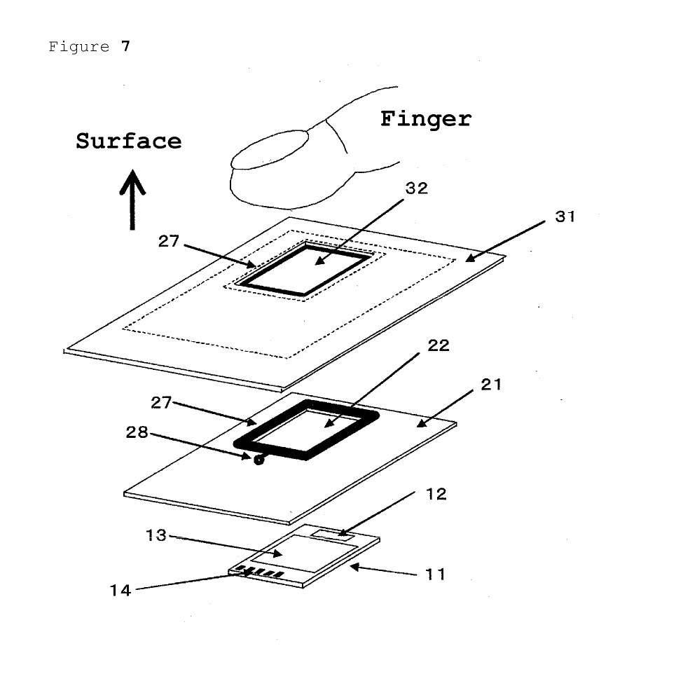

As shown in FIG. 7, there formed another rectangular strip pattern 27 on the film substrate 21, surrounding where the width of the strip pattern 27 is appropriately pre-determined for a finger to establish a direct contact with the strip pattern 27, and furthermore, the size of the aperture 32 of the over sheet 31 is also appropriately pre-determined so that part of the strip pattern 27 may be exposed to allow a finger to establish a direct contact with the strip pattern 27 when the finger is placed on the sensing area 13 of the smartcard of the present invention.

The rectangular strip pattern 27 is made of metal for the electrical conductivity, and may be gold plated against the surface deterioration. The rectangular strip pattern 27 is connected the component surface of the film substrate 21 via the through electrode 28, which establishes the electrical connection with the signal line on the core substrate.

The above described signal line may measure the dielectric constant and/or the electrostatic capacitance as an object touches the fingerprint image acquisition sensor IC chip 11, it is possible to determine if the object is a live finger or a fake one made of silicone rubber, urethane rubber, and other similar materials.

### INDUSTRIAL FIELD OF APPLICATION

The present invention may provide a smartcard which is integrated with an ultra thin fingerprint image acquisition sensor and the thickness is 0.76 mm or less as determined with the ISO standard.

### EXPLANATION OF REFERENCE NUMERALS

1 is the reinforcing plate for the fingerprint image acquisition sensor IC chip.
11 is the fingerprint image acquisition sensor IC chip.
12 is the area of sensing the physical contact of a finger.
13 is the area of acquiring a fingerprint image.
14 is the external connection terminals (the pads) of the fingerprint image acquisition sensor IC chip for interfacing the chip with external devices.
15 is the control unit of the fingerprint image acquisition sensor IC chip.
21 is the film substrate (or sometimes called the flexible printed circuit (FPC)).
22 is the aperture formed on the film substrate.
23 is the junction of the fingerprint with the external connection terminals, formed on the film substrate.
24 is the electrical circuit pattern formed on the film substrate.
25 is the array of the external connection terminals formed on the film substrate.
26 is the conductive pattern which is formed on the component surface of the film substrate to protect the control circuit of the fingerprint image acquisition sensor IC chip.
27 is the conductive pattern to detect liveness of a finger touch the fingerprint image acquisition sensor IC chip.
28 is the through electrode that connects the conductive pattern 27 to the film substrate 21.
31 is the over sheet.
32 is the aperture formed on the over sheet.
33 is the under sheet.
41a is the reinforcement and encapsulation layer of adhesive formed between the fingerprint image acquisition sensor IC chip and the film substrate.
41b is the reinforcement and encapsulation layer of adhesive formed between the fingerprint image acquisition sensor IC chip and the film substrate.

What is claimed is:

1. A smartcard which embeds a fingerprint image acquisition sensor IC chip, comprising:
a film substrate, which is formed on the sensor IC chip which has a detection unit and a sensing area on its front surface,
an aperture formed on the film substrate for exposing the detection unit ad the sensing area,
an electric circuit and components for driving the fingerprint sensor formed on the backside of the film substrate,
where the backside of the film substrate is adhered to the front surface of the IC chip with adhesive.

2. The smartcard which embeds the fingerprint image acquisition sensor IC chip of the claim 1, wherein,
a connection terminal, which is used to interface the fingerprint image acquisition sensor IC chip with the circuit formed on the back surface of the film substrate, is formed on the surface layer of the fingerprint image acquisition sensor IC chip for adhering the connection terminal with the electrical circuit which is formed on the back surface of the film substrate.

3. The smartcard which embeds the fingerprint image acquisition sensor IC chip of the claim 1, wherein,
the adhesion of the connection terminal with the circuit formed on the back surface of the film substrate is achieved by applying an anisotropic conductive adhesive film, an anisotropic conductive adhesive paste, or solder.

4. The smartcard which embeds the fingerprint image acquisition sensor IC chip of the claim 3, wherein,
a reinforcement and encapsulation layer of adhesive material is formed on the side surface of the sensor IC chip after adhering the connection terminal with the electrical circuit which is formed on the back surface of the film substrate.

5. The smartcard which embeds the fingerprint image acquisition sensor IC chip of the claim 3, wherein,
a reinforcement plate is attached on the back surface of the sensor IC chip and also a reinforcement and encapsulation layer of adhesive material is formed on the side surface of the sensor IC chip after adhering the connection terminal with the electrical circuit which is formed on the back surface of the film substrate.

6. The smartcard which embeds the fingerprint image acquisition sensor IC chip of the claim 1, wherein,
the fingerprint image acquisition sensor IC chip equips a control unit which reads, controls, and output data from the fingerprint image acquisition sensor, and a conductive pattern which is formed on the back surface of the film substrate, surrounding the control unit, and is grounded.

7. The smartcard which embeds the fingerprint image acquisition sensor IC chip of the claim 1, wherein,
a conductive strip pattern is formed on the outer rim of the aperture of the film substrate, having adequate width for a finger to establish a direct physical contact with the conductive strip pattern in order to obtain an electric signal of contacting the finger with the conductive strip patter for determining if the contacting finger is live or artificial finger.
